(19) United States
(12) Patent Application Publication
(10) Pub. No.: US 2025/0324916 A1
(43) Pub. Date: Oct. 16, 2025

(54) PROCESSING A MEMORY ARRAY WITH REDUCED DRIFT

(71) Applicant: Micron Technology, Inc., Boise, ID (US)

(72) Inventors: Agostino Pirovano, Milano (IT); Innocenzo Tortorelli, Cernusco Sul Naviglio (IT); Nirav D. Vora, Meridian, ID (US)

(21) Appl. No.: 18/789,472

(22) Filed: Jul. 30, 2024

Related U.S. Application Data
(60) Provisional application No. 63/633,152, filed on Apr. 12, 2024.

(51) Int. Cl. H10N 70/00; H10B 63/00

(52) U.S. Cl. CPC H10N 70/021; H10B 63/80; H10N 70/063; H10N 70/066; H10N 70/841; H10N 70/882

(57) ABSTRACT

Processing a memory array with reduced drift is described herein. An example method includes forming, on a substrate material, a first conductive line material, forming, on the first conductive line material, a first electrode material and a second electrode material separated from one another by a sacrificial material, and forming a plurality of openings in the first conductive line material, first electrode material, sacrificial material, and second electrode material. An insulation material is formed in the plurality of openings. A second conductive line material is formed on the second electrode material and insulation material. An additional plurality of openings are formed in the first electrode material, sacrificial material, second electrode material, and second conductive line material. A plurality of recesses are formed between the first electrode material and the second electrode material by selectively removing the sacrificial material. A chalcogenide material is formed in the plurality of recesses.

### PRIORITY INFORMATION

This application claims the benefit of U.S. Provisional Application No. 63/633,152, filed on Apr. 12, 2024, the contents of which are incorporated herein by reference.

### TECHNICAL FIELD

The present disclosure relates generally to semiconductor memory and methods, and more particularly, to processing a memory array with reduced drift.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Resistance variable memory devices can include resistance variable memory cells that can store data based on the resistance state of a storage element (e.g., a memory element having a variable resistance). As such, resistance variable memory cells can be programmed to store data corresponding to a target data state by varying the resistance level of the memory element. Resistance variable memory cells can be programmed to a target data state (e.g., corresponding to a particular resistance state) by applying sources of an electrical field or energy, such as positive or negative electrical pulses (e.g., positive or negative voltage or current pulses) to the cells (e.g., to the memory element of the cells) for a particular duration. A state of a resistance variable memory cell can be determined by sensing current through the cell responsive to an applied interrogation voltage. The sensed current, which varies based on the resistance level of the cell, can indicate the state of the cell.

Various memory arrays can be organized in a cross-point architecture with memory cells (e.g., resistance variable cells) being located at intersections of a first and second signal lines used to access the cells (e.g., at intersections of word lines and bit lines). Some resistance variable memory cells can comprise a select element (e.g., a diode, transistor, or other switching device) in series with a storage element (e.g., a phase change material, metal oxide material, and/or some other material programmable to different resistance levels). Some resistance variable memory cells, which may be referred to as self-selecting memory cells, can comprise a single material which can serve as both a select element and a storage element for the memory cell.

### BRIEF DESCRIPTION OF THE DRAWINGS

FIG. 1 illustrates a cross-sectional view of a processing step associated with forming a memory array, in accordance with an embodiment of the present disclosure.

FIGS. 2A and 2B illustrate various views of a subsequent processing step associated with forming the memory array, in accordance with an embodiment of the present disclosure.

FIGS. 3A and 3B illustrate various views of a subsequent processing step associated with forming the memory array, in accordance with an embodiment of the present disclosure.

FIGS. 4A-4C illustrate various views of a subsequent processing step associated with forming the memory array, in accordance with an embodiment of the present disclosure.

FIGS. 5A and 5B illustrate various views of a subsequent processing step associated with forming the memory array, in accordance with an embodiment of the present disclosure.

FIGS. 6A and 6B illustrate various views of a subsequent processing step associated with forming the memory array, in accordance with an embodiment of the present disclosure.

FIGS. 7A and 7B illustrate various views of a subsequent processing step associated with forming the memory array, in accordance with an embodiment of the present disclosure.

FIG. 8 is a three-dimensional view of an example memory array, in accordance with an embodiment of the present disclosure.

FIG. 9 is a block diagram of an apparatus in the form of a memory device, in accordance with an embodiment of the present disclosure.

### DETAILED DESCRIPTION

The present disclosure includes memory arrays, and processing memory arrays, with reduced drift. A number of embodiments include forming, on a substrate material, a first conductive line material, forming, on the first conductive line material, a first electrode material and a second electrode material separated from one another by a sacrificial material, and forming a plurality of openings in the first conductive line material, the first electrode material, the sacrificial material, and the second electrode material. An insulation material is formed in the plurality of openings. A second conductive line material is formed on the second electrode material and the insulation material. An additional plurality of openings are formed in the first electrode material, the sacrificial material, the second electrode material, and the second conductive line material. A plurality of recesses are formed between the first electrode material and the second electrode material by selectively removing the sacrificial material. A chalcogenide material is formed in the plurality of recesses.

A memory array in accordance with the present disclosure can be a planar cross-point memory array. Additionally, a memory array in accordance with the present disclosure can have increased performance as compared with previous memory arrays. For example, the performance of a memory array in accordance with the present disclosure can be increased compared to the performance of previous planar cross-point memory arrays due to the integration of low-drift alloys with lower glass-transition temperatures for use as the storage element.

As performance requirements for memory increase, storage elements that are able to withstand the high power consumption associated with the high selection voltages applied to the storage element and repeated polarity switching of the storage element (e.g. reprogramming the storage element to a different data state by applying positive or negative electrical pulses) are needed. Past approaches have utilized chalcogenide alloys with a glass-transition temperature high enough (e.g., greater than 320 degrees Celsius) to withstand the high temperatures used during previous approaches (e.g., subtractive approaches) used for processing planar cross-point memory arrays. This, however, can limit the choice of suitable chalcogenide alloys to alloys with a minimum Germanium content of over 13%. Such chalcogenide alloys can have high set and reset drifts, thereby reducing the read-write performance and increasing read latency of the memory.

The performance of a memory array can refer to the read or write latency and single bit addressability of the memory array. The performance of a memory array can be impacted by the set or reset drift of the storage element of the memory cells of a memory array. Drift refers to any gradual and/or unintended changes of stored data values in memory cells over time. Drift can be impacted by the physical properties of the storage element materials used in the memory array, temperature fluctuations affecting the stability of the memory cells, and voltage stress caused by repeated reprogramming of memory cells. The performance of memory arrays in accordance with the present disclosure can be increased due to the integration of alloys with a Germanium content of less than 13% (e.g., less than or equal to 10%) for use as the storage element. Accordingly, the performance of a memory array can be increased by reducing the set and reset drift by a factor of at least 3 compared to previous memory arrays through the integration of such alloys with low glass-transition temperatures (e.g., less than 320 degrees Celsius).

Forming a memory array in accordance with the present disclosure can include forming a chalcogenide material within a plurality of recesses that were previously filled with a placeholder material during earlier stages of the processing sequence. This processing approach (which can be referred to as a chalcogenide-last approach) can use lower temperatures than previous (e.g., subtractive) processing approaches, which allows for chalcogenide alloys that do not need to withstand the high temperature of such previous approaches to be used as the storage element.

As used herein, “a”, “an”, or “a number of” can refer to one or more of something, and “a plurality of” can refer to two or more such things. For example, a memory device can refer to one or more memory devices, and a plurality of memory devices can refer to two or more memory devices. Additionally, the designators “N” and “M”, as used herein, particularly with respect to reference numerals in the drawings, indicates that a number of the particular feature so designated can be included with a number of embodiments of the present disclosure.

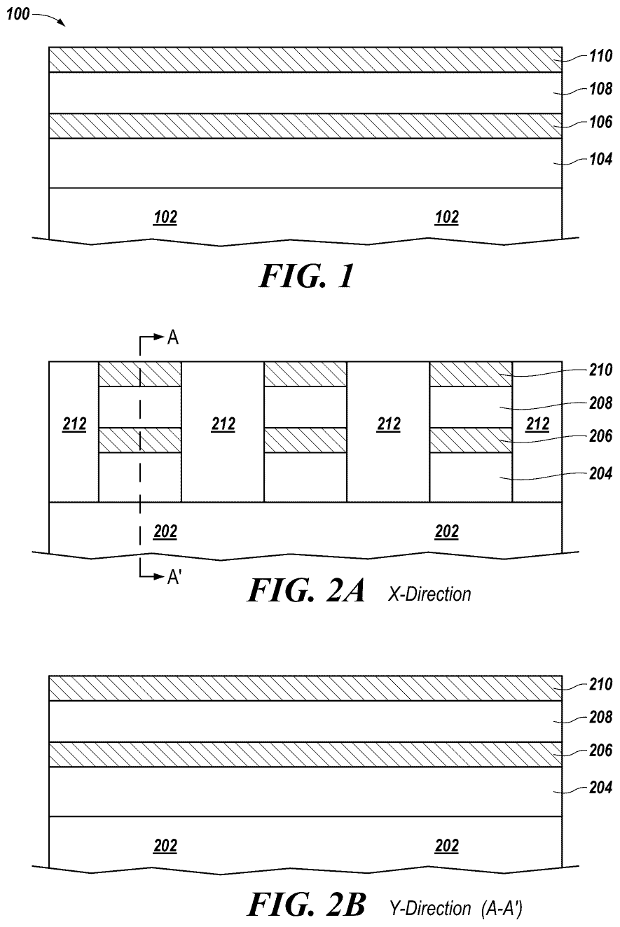

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and a similar element may be referenced as 202 in FIGS. 2A and 2B.

FIG. 1 illustrates a cross-sectional view of a processing step associated with forming a planar memory array 100 in accordance with an embodiment of the present disclosure. FIG. 1 shows a plurality of planes of associated materials separated in a y-direction (e.g., separated vertically) from one another. For example, a first conductive line material 104 is formed (e.g., deposited) on a substrate material 102. The substrate material 102, for example, can be a dielectric material such as an oxide material. A dielectric material is a material that does not conduct electric current easily but has the ability to store and manipulate electrical charges thereby acting as an insulator. The first conductive line material 104 can be a metal material, such as tungsten, for example.

FIG. 1 further shows a first electrode material 106 and a second electrode material 110 separated from one another by a sacrificial material 108 are formed on the first conductive line material 104. The first and second electrode materials may be carbon, for example. The sacrificial material 108 can act as a placeholder material and can be a single dielectric material (e.g., silicon oxide or silicon nitride), a polysilicon material, or a multi-stack of different dielectric materials (SiN/SiO₂/SiN), for example.

FIGS. 2A and 2B illustrate various views of a subsequent processing step associated with forming the memory array, in accordance with an embodiment of the present disclosure. FIG. 2A illustrates a cross-sectional view in an x-direction of the subsequent processing step. FIG. 2B illustrates a cross-sectional view along a cut line A-A′ (depicted in FIG. 2A) in a y-direction of the subsequent processing step.

In the example shown in FIG. 2A, a plurality of openings (e.g., trenches) are formed (e.g., etched and or/patterned) in the first conductive line material 204, the first electrode material 206, the sacrificial material 208, and the second electrode material 210. The plurality of openings can be formed in a grid pattern along a first direction. The first direction can be a vertical direction with respect to the array, such that the plurality of openings are formed downward into the plurality of planes. For example, the plurality of openings can be formed through the plurality of planes such that portions of the first conductive line material 204, the first electrode material 206, the sacrificial material 208, and the second electrode material 210 are removed in an alternating pattern. For example, the plurality of openings can be formed in a staggered arrangement with equal spacing between each of the plurality of openings.

The plurality of openings can be formed through a selective etching process; however, embodiments in accordance with the present disclosure are not so limited. The etching process can include selectively removing material (e.g., portions of materials 204, 206, 208, and 210) from the substrate 102 by using an etchant for planarization. The etchant can react with and remove a selected material or plurality of materials. The process of etching can involve applying the etchant to a surface for a specific duration of time, allowing for the selective removal of the selected material in the exposed areas. Selective etching can also include masking techniques, in which certain areas are protected from the etchant to create a specific pattern. Each of the plurality of openings can be formed at the same time. For instance, each of the plurality of openings can be formed in a single etch and/or pattern using a single mask. Mask patterning can aid in defining the functionality of memory arrays through precise alignment of deposited materials.

FIG. 2A shows an insulation material 212 formed (e.g., deposited) in the plurality of openings. The insulation material can be a dielectric material, such as a silicon nitride (SiN) material. The insulation material 212 can be a different material than the sacrificial material 208 to facilitate the selective etching process. Alternatively, the insulation material 212 can be the same material as the sacrificial material 208. Alternative sealing/filling can be used depending on the sacrificial material 208 being removed (e.g., hafnium oxide (or HfOₓ) sealing with SiO₂ filling for removing a nitride sacrificial material).

A planarization process can be performed after the insulation material 212 is formed in the plurality of openings. Planarization can involve creating a flat surface after a processing step is performed to facilitate subsequent processing steps involving the formation/deposition of additional layers. Planarization can be performed using any suitable technique to remove excess material.

FIG. 2B illustrates a cross-sectional view along cut line A-A′ in a y-direction of the subsequent processing step illustrated in FIG. 2A. FIG. 2B shows the remaining portions of materials 204, 206, 208, and 210 not removed in the process of forming the openings in which insulation material 212 is formed. Due to the mask patterning utilized with the formation of the plurality of openings, the previously formed substrate material 202, first conductive line material 204, and first and second electrode materials separated from one another by the sacrificial material remain intact in between the insulation material 212.

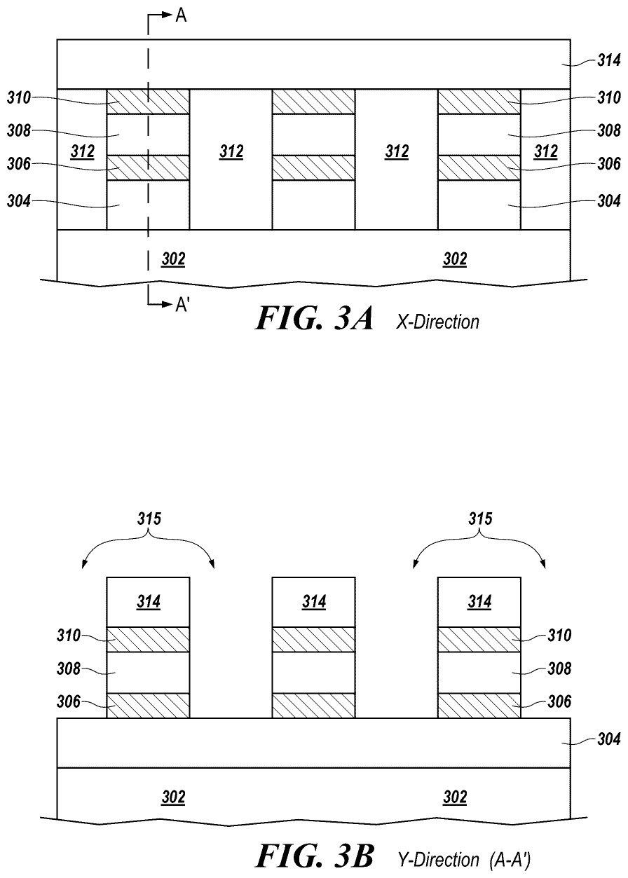

FIGS. 3A and 3B illustrate various views of a subsequent processing step associated with forming the memory array, in accordance with an embodiment of the present disclosure. FIG. 3A depicts a cross-sectional view of the subsequent processing step in the x-direction. FIG. 3B depicts a cross-sectional view along cut line A-A′ (shown in FIG. 3A) of the subsequent processing step in the y-direction.

FIGS. 3A and 3B illustrate a second conductive line material 314 formed (e.g., deposited) on the second electrode material 310 and the insulation material 312. The second conductive line material 314 can be a metal material, such as tungsten, for example. The second conductive line material 314 can be deposited on any exposed area such that the second conductive line material 314 is formed on the insulation material 312 and the second electrode material 310. As part of the formation of the second conductive line material, selective etching can be used to aid in the precise alignment of the second conductive line material on the memory array.

Selective etching can include masking techniques, where certain areas are protected from the etchant to create a specific pattern. For instance, the second conductive line material can be formed in a single etch and/or pattern using a single mask. Mask patterning can aid in defining the functionality of memory arrays through precise alignment of deposited materials.

FIG. 3B depicts a cross-sectional view along the cut line A-A′ (depicted in FIG. 3A) in a y-direction of the subsequent processing step depicted in FIG. 3A. As shown in FIG. 3B, a plurality of openings 315 are formed (e.g., etched and or/patterned) in the first electrode material 306, the sacrificial material 308, the second electrode material 310 and the second conductive line material 314. The plurality of openings 315 can be formed in the grid pattern along the first direction (e.g., in a vertical direction with respect to the array, such that the plurality of openings 315 are formed downward into the plurality of planes). For example, the plurality of openings 315 can be formed through the plurality of planes such that portions of the first electrode material 306, the sacrificial material 308, the second electrode material 310, and the second conductive line material 314 are removed in an alternating pattern. For example, the plurality of openings 314 can be formed in a staggered arrangement with equal spacing between each of the plurality of openings.

As illustrated in FIG. 3B, after the second conductive line material 314 is deposited and the plurality of openings 315 are formed, these alternating sections form a plurality of stacks. Each of the plurality of stacks comprise the first electrode material 306, the sacrificial material 308, the second electrode material 310, and the second conductive line material 314. The plurality of stacks can be precisely defined through the selective etching/mask patterning included in the formation of the second conductive line material on the memory array. The second conductive line material is formed such that the second conductive line material 314 of each respective one of the plurality of stacks is substantially perpendicular to the first conductive line material 304.

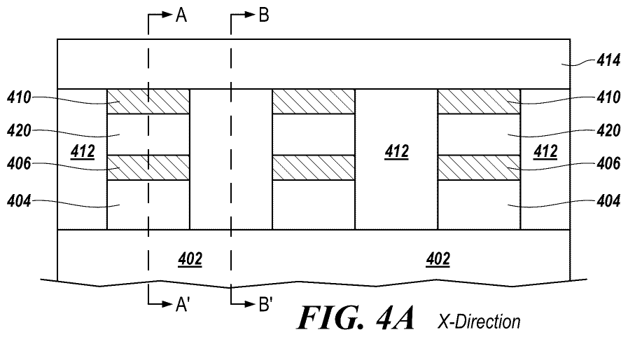

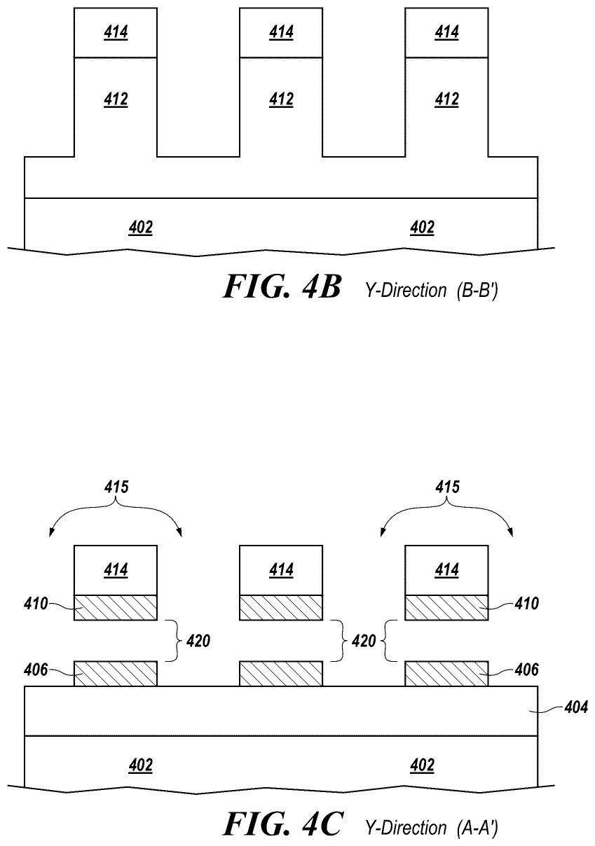

FIGS. 4A-4C illustrate various views of a subsequent processing step associated with forming the memory array, in accordance with an embodiment of the present disclosure. FIG. 4A illustrates a cross-sectional view of the subsequent processing step in the x-direction. FIG. 4B illustrates a cross-sectional view along cut line B-B′ (shown in FIG. 4A) in the y-direction of the subsequent processing step. FIG. 4C illustrates a cross-sectional view along cut line A-A′ (shown in FIG. 4A) in the y-direction of the subsequent processing step.

FIGS. 4A and 4C show a plurality of recesses 420 formed between the first electrode material 406 and the second electrode material 410 by selectively removing the sacrificial material 308. The sacrificial material may be selectively removed (e.g., exhumed) through an etching process. As used herein, a “selective etching process” refers to a method of exhuming the placeholder material only, such that other materials (e.g., materials 402, 404, 406, 410, and 414) remain intact. As previously described, the etchant can be chosen to react with and remove a selected material (e.g., the sacrificial material). The process of etching can include applying the etchant to a surface for a specific duration of time, allowing for the selective removal of the selected material in the exposed areas.

As illustrated in FIGS. 4A and 4C, the plurality of recesses 420 are formed between the first electrode material 406 and the second electrode material 410 along a second direction that is perpendicular to the first direction of the plurality of openings (as described in reference to FIG. 2A). The second direction is different than the first direction. For example, the second direction can be horizontal with respect to the memory array (e.g., along an x-direction of the memory array).

FIG. 4B illustrates a cross-sectional view along the cut line B-B′ of FIG. 4A in the y-direction. During the selective etching process, mechanical stability can be provided by the insulation material 412. As illustrated in FIG. 4B, the insulation material remains untouched during the selective etch such that a plurality of pillars of insulation material 412 are formed.

FIG. 4C illustrates a cross-sectional view along the cut line A-A′ of FIG. 4A in the y-direction. As illustrated in FIG. 4C, the plurality of recesses 420 alternate (e.g., skip) columns in the y-direction. For instance, the plurality of recesses are in line with each other in the y-direction (e.g., columns) but the plurality of recesses alternate (e.g., skip) rows in the y-direction.

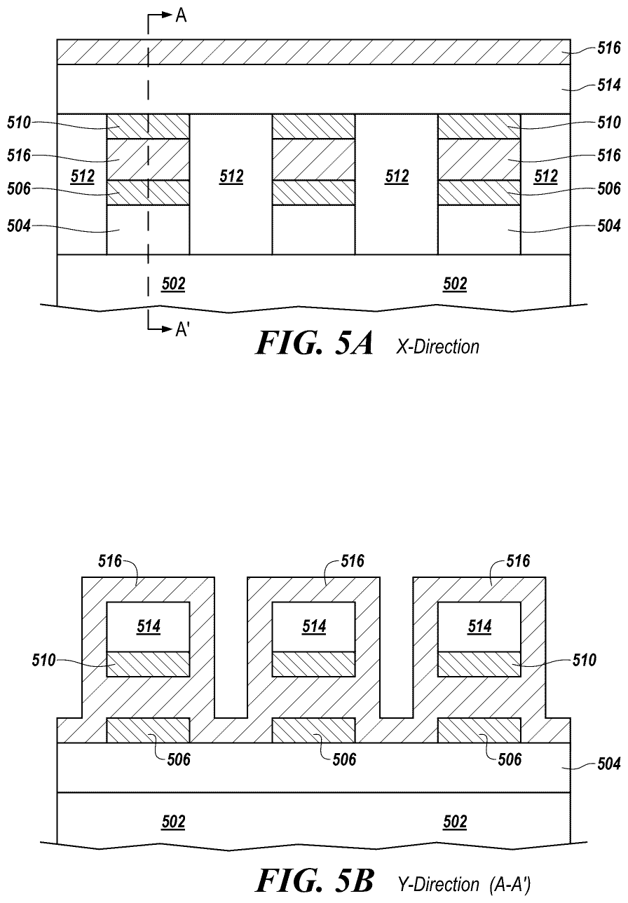

FIGS. 5A and 5B illustrate various views of a subsequent processing step associated with forming the memory array, in accordance with an embodiment of the present disclosure. FIG. 5A illustrates a cross-sectional view of the subsequent processing step in the x-direction. FIG. 5B illustrates a cross-sectional view of the subsequent processing step along cut line A-A′ (illustrated in FIG. 5A) in the y-direction.

As shown in FIGS. 5A and 5B, a chalcogenide material 516 can be formed (e.g., deposited) onto the memory array such that the chalcogenide material 516 is formed in the plurality of recesses 420. The chalcogenide material 516 may be formed using atomic layer deposition, for example. Atomic layer deposition is a technique involving layer-by-layer deposition with atomic-level precision. The chalcogenide material 516 may be formed within the plurality of recesses by depositing the chalcogenide material 516 on the second conductive line material 514 such that the chalcogenide material 514 is formed on the second conductive line material 514, in the plurality of recesses, and on the sidewall of the plurality of openings 415.

The chalcogenide material 516, which can be a chalcogenide alloy and/or glass, for example, can serve as a self-selecting storage element material (e.g., a material that can serve as both a select device and a storage element). For example, the chalcogenide material 516 can be responsive to an applied voltage, such as a program pulse, applied thereto. For an applied voltage that is less than a threshold voltage, the chalcogenide material may remain in an electrically nonconductive state (e.g., an “off” state). Alternatively, responsive to an applied voltage that is greater than the threshold voltage, the chalcogenide material 516 may enter an electrically conductive state (e.g., an “on” state). Further, the threshold voltage of the chalcogenide material in a given polarity can change based on the polarity (e.g., positive or negative) of the applied voltage. For instance, the threshold voltage can change based on whether the polarity of the program pulse is positive or negative.

Chalcogenide material 516 may be materials or alloys that include at least one of the elements S, Se, and Te. Chalcogenide material 516 may include alloys of S, Se, Te, Ge, As, Al, Sb, Au, indium (In), gallium (Ga), tin (Sn), bismuth (Bi), palladium (Pd), cobalt (Co), oxygen (O), silver (Ag), nickel (Ni), platinum (Pt). Example chalcogenide materials and alloys may include, but are not limited to, Ge-Te, In-Se, Sb-Te, Ga-Sb, In-Sb, As-Te, Al-Te, Ge-Sb-Te, Te-Ge-As, In-Sb-Te, Te-Sn-Se, Ge-Se-Ga, Bi-Se-Sb, Ga-Se-Te, Sn-Sb-Te, In-Sb-Ge, Te-Ge-Sb-S, Te-Ge-Sn-O, Te-Ge-Sn-Au, Pd-Te-Ge-Sn, In-Se-Ti-Co, Ge-Sb-Te-Pd, Ge-Sb-Te-Co, Sb-Te-Bi-Se, Ag-In-Sb-Te, Ge-Sb-Se-Te, Ge-Sn-Sb-Te, Ge-Te-Sn-Ni, Ge-Te-Sn-Pd, or Ge-Te-Sn-Pt. Example chalcogenide materials can also include SAG-based glasses NON phase change materials such as SeAsGe. The hyphenated chemical composition notation, as used herein, indicates the elements included in a particular compound or alloy and is intended to represent all stoichiometries involving the indicated elements. For example, Ge-Te may include GexTey, where x and y may be any positive integer.

Examples of chalcogenide materials that can serve as chalcogenide material 516 include indium (In)-antimony (Sb)-tellurium (Te) (IST) materials, such as In₂Sb₂Te₇, In₁Sb₂Te₄, In₁Sb₄Te₇, etc., and germanium (Ge)-antimony (Sb)-tellurium(Te) (GST) materials, such as Ge₈Sb₅Te₈, Ge₂Sb₂Te₅, Ge₁Sb₂Te₄, Ge₁Sb₄Te₇, Ge₄Sb₄Te₇, or etc., among other chalcogenide materials, including, for instance, alloys that do not change phase during the operation (e.g., selenium-based chalcogenide alloys). Further, the chalcogenide material 516 may include minor concentrations of other dopant materials. In some embodiments, the chalcogenide material 516 can be an alloy having a Germanium content of less than 13% (e.g., less than or equal to 10%). In some embodiments, the chalcogenide material 516 can be an alloy having a glass transition temperature of less than 320 degrees Celsius.

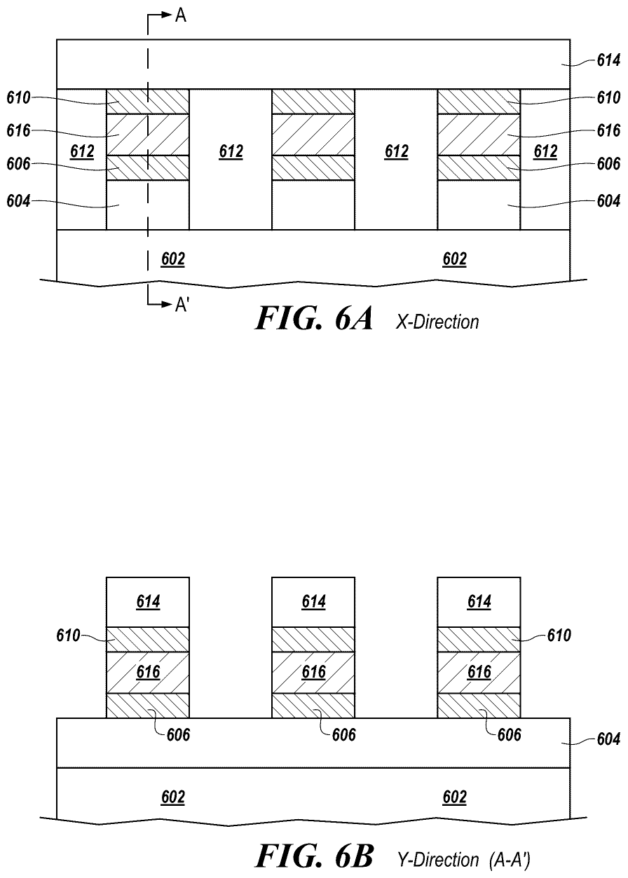

FIGS. 6A and 6B illustrate various views of a subsequent processing step associated with forming the memory array, in accordance with an embodiment of the present disclosure. FIG. 6A illustrates a cross-sectional view of the subsequent processing step along the x-direction. FIG. 6B illustrates a cross-sectional view of the subsequent processing step along cut line A-A′ (illustrated in FIG. 6A) in the y-direction.

As illustrated in FIGS. 6A and 6B, excess chalcogenide material (e.g., chalcogenide material formed in areas other than the plurality of recesses 420) is removed. For instance, the chalcogenide material 616 can be removed from the second conductive line material 614 and the sidewall of the plurality of openings 415 such that the chalcogenide material remains only in the plurality of recesses 420.

The chalcogenide material can be removed through an etchback process, for example. The etchback process can be a hydrogen bromide (HBr) based dry etch process, for example. The chalcogenide etchback can be a single step process, thereby reducing any compositional transformation along the sidewall compared to a standard subtractive approach. The standard subtractive approach can include a multi-etch process such that extra material remains on the sidewall after the etching is complete. In the single-step approach of the present disclosure, however, there may be no additional material remaining on the sidewall such that there is direct contact between the sidewall of the plurality of openings 415 and the chalcogenide material 616 formed in the plurality of recesses. For instance, the chalcogenide material 616 formed within the plurality of recesses 420 can be in direct contact with the insulation material 612.

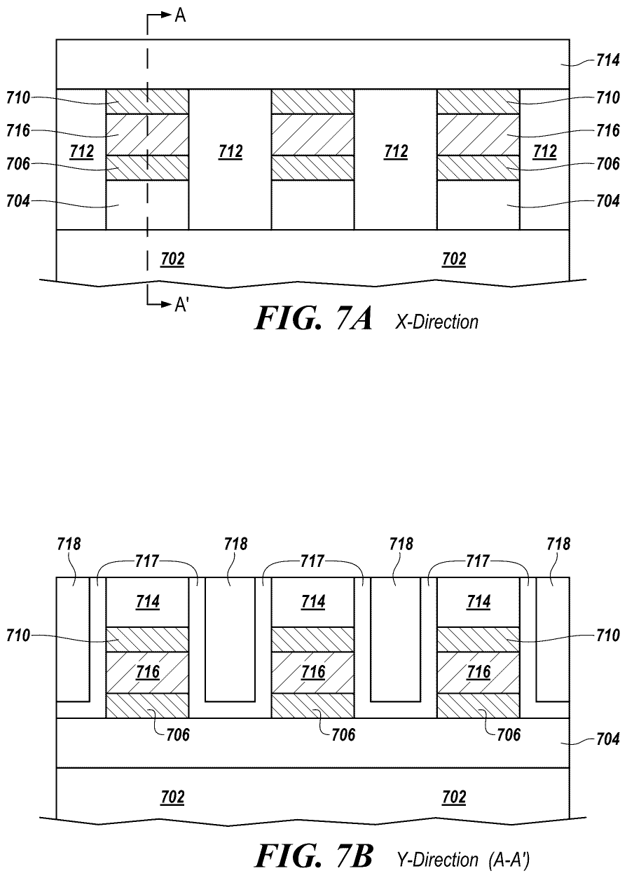

FIGS. 7A and 7B illustrate various views of a subsequent processing step associated with forming the memory array, in accordance with an embodiment of the present disclosure. FIG. 7A illustrates a cross-sectional view of the subsequent processing step in the x-direction. FIG. 7B illustrates a cross-sectional view of the subsequent processing step along cut line A-A′ (illustrated in FIG. 7A) in the y-direction.

As shown in FIGS. 7A-7B, an additional insulation material 717 (e.g., a sealing dielectric material) can be formed in the plurality of openings 415 (e.g., on the sidewall of the plurality of openings 415) such that the additional insulation material 717 is in direct contact with the sidewall of each respective one of the plurality of openings 415. A further insulation material 718 (e.g., a filling dielectric material) can be formed in the remaining portion of openings 415, as illustrated in FIGS. 7A-7B.

The sealing dielectric material can be SiN, for example, with SiO₂ used as the filling dielectric material, for instance. The sealing dielectric material can be a low-temperature material. The sealing and filling dielectric materials may be deposited in the exposed area remaining after the chalcogenide etchback process described in connection with FIGS. 6A-6B is performed. FIG. 7B depicts the sealing dielectric material 717 formed along the sidewall of the plurality of openings 415 and on the first conductive line material 704 between the plurality of stacks such that the outer surface of each stack is coated with the sealing dielectric material. The filling dielectric material 718 can be formed within the remaining exposed area such that the filling material 718 is in direct contact with the sealing dielectric material 717.

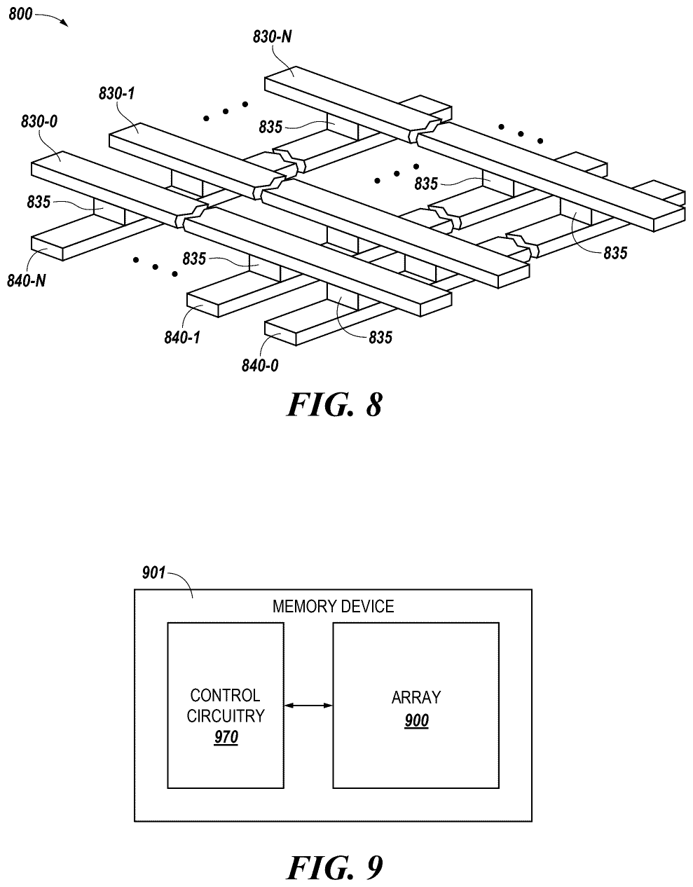

FIG. 8 is a three-dimensional view of an example of a memory array 800 (e.g., a cross-point memory array), in accordance with an embodiment of the present disclosure. Memory array 800 can correspond to memory array 100 after the processing step described in connection with FIGS. 7A-7B.

Memory array 800 may include a plurality of first signal lines (e.g., access lines), which may be referred to as word lines 840-0 to 840-N, and a plurality of second signal lines (e.g., sense lines), which may be referred to as bit lines 830-0 to 830-M that cross each other (e.g., intersect in different planes). For example, each of word lines 840-0 to 840-N may cross bit lines 830-0 to 830-M. Each respective word line 840 can correspond to (e.g., comprise) a different first conductive line material 704, and each respective bit line 830 can correspond to (e.g., comprise) a different second conductive line material 714. A memory cell 835 may be between the bit line and the word line (e.g., at each bit line/word line crossing).

The memory cells 835 may be resistance variable memory cells, for example. The memory cells 835 may include a material programmable to different data states. For example, each respective memory cell 835 can include a different respective chalcogenide material 716. In some examples, each of memory cells 835 may include a single chalcogenide material 716, between a top electrode (e.g., top plate) 710 and a bottom electrode (e.g., bottom plate) 706, that may serve as a select element (e.g., a switching material) and a storage element, so that each memory cell 835 may act as both a selector device and a memory element. Such a memory cell may be referred to herein as a self-selecting memory cell.

The architecture of memory array 800 may be referred to as a cross-point architecture in which a memory cell is formed at a topological cross-point between a word line and a bit line as illustrated in FIG. 8. Such a cross-point architecture may offer relatively high-density data storage with lower production costs compared to other memory architectures. For example, the cross-point architecture may have memory cells with a reduced area and, resultantly, an increased memory cell density compared to other architectures.

As an example, with reference to FIG. 7A, memory array 800 can include substrate material 702, and a plurality of stacks formed on substrate material 702. Each respective one of the plurality of stacks can include a first conductive line 704 (e.g., one of word lines 840), a first (e.g., bottom) electrode 706 formed on the first conductive line 704, a chalcogenide material 716 formed on the first electrode 706, and a second (e.g., top) electrode 710 formed on the chalcogenide material 716. Memory array 800 can further include a second conductive line 714 (e.g., one of bit lines 830) formed on the second electrode 710 of each respective one of the plurality of stacks. The plurality of stacks can be separated from one another by insulation material 712 in direct contact with the sidewall of each respective stack. Each respective memory cell 835 can include the first electrode, chalcogenide material, and second electrode of one of the stacks.

The memory cells 835 of the memory array 800 can be coupled to control circuitry (not shown in FIG. 8). The control circuitry can be used to select a particular one of the memory cells 835 during a program or sense operation, for example, as described further in association with FIG. 9.

FIG. 9 is a block diagram of an apparatus in the form of a memory device 901 in accordance with an embodiment of the present disclosure. As used herein, an “apparatus” can refer to, but is not limited to, any of a variety of structures or combinations of structures, such as a circuit or circuitry, a die or dies, a module or modules, a device or devices, or a system or systems, for example. As shown in FIG. 9, the memory device 901 can include a memory array 900. The memory array 900 can be analogous to memory array 800 previously described in connection with FIG. 8. Although FIG. 9 shows a single memory array 900 for clarity and so as not to obscure embodiments of the present disclosure, the memory device 901 may include any number of memory arrays analogous to array 900.

As shown in FIG. 9, the memory device 901 can include control circuitry 970 coupled to the memory array 900. The control circuitry 970 can be included on the same physical device (e.g., the same die) as the memory array 900, or can be included on a separate physical device that is communicatively coupled to the physical device that includes the memory array 900.

In general, the control circuitry 970 can receive information or operations from a host system (not illustrated) and convert the information or operations into instructions or appropriate information to achieve the desired access to the memory device 901. The control circuitry can be responsible for other operations such as wear leveling operations, error detection, and/or correction operations, encryption operations, caching operations, and address translations between a logical address (e.g., logical block address) and a physical address (e.g., physical block address) associated with the memory device 901. The control circuitry 970 can further include host interface circuitry (not illustrated) to communicate with the host system.

The control circuitry 970 can include hardware such as one or more integrated circuits and/or discrete components, a buffer memory, or a combination thereof. The control circuitry can be special purpose logic circuitry (e.g., a field programmable gate array (FPGA), an application specific integrated circuit (ASIC), etc.), or other suitable circuitry.

The control circuitry 970 can send commands to perform operations on the memory array 900, such as operations to sense (e.g., read), program (e.g., write), move, and/or erase data, among other operations. For example, the control circuitry 970 can include portions of control circuitry for use in selecting a particular memory cell of the memory array 900 to access during a program or sense operation. For instance, a first portion of the control circuitry can be used to select a data line (e.g., one of the first plurality of conductive lines 830-0 . . . 830-N described in association with FIG. 8) coupled to the memory cell, and a second portion of the control circuitry can be used to select an access line (e.g., 840-0 . . . 840-N illustrated in FIG. 8) coupled to the memory cell.

The embodiment illustrated in FIG. 9 can include additional circuitry, logic, and/or components not illustrated so as not to obscure embodiments of the present disclosure. Further, the memory device 901 can include address circuitry to latch address signals provided over input/output (I/O) connectors through I/O circuitry. Further, the memory device 901 can include a main memory, such as, for instance, a DRAM or SDRAM, that is separate from and/or in addition to the memory array(s) 900.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method of processing a memory array, comprising:
forming, on a substrate material, a first conductive line material;
forming, on the first conductive line material, a first electrode material and a second electrode material separated from one another by a sacrificial material;
forming a plurality of openings in the first conductive line material, the first electrode material, the sacrificial material, and the second electrode material;
forming an insulation material in the plurality of openings;
forming, on the second electrode material and the insulation material, a second conductive line material;
forming an additional plurality of openings in the first electrode material, the sacrificial material, the second electrode material, and the second conductive line material;
forming a plurality of recesses between the first electrode material and the second electrode material by selectively removing the sacrificial material; and
forming a chalcogenide material in the plurality of recesses.

2. The method of claim 1, wherein forming the chalcogenide material in the plurality of recesses comprises depositing the chalcogenide material on the second conductive line material such that the chalcogenide material is formed on the second conductive line material, in the plurality of recesses, and on a sidewall of the additional plurality of openings.

3. The method of claim 2, further comprising removing the chalcogenide material from the second conductive line material and the sidewall of the additional plurality of openings.

4. The method of claim 3, further comprising forming an additional insulation material on the sidewall of the additional plurality of openings.

5. The method of claim 1, wherein the plurality of openings are formed in a grid pattern.

6. The method of claim 1, wherein the sacrificial material is a silicon oxide material.

7. The method of claim 1, wherein the insulation material is a dielectric material.

8. The method of claim 1, wherein the chalcogenide material is an alloy having a Germanium content of less than 13%.

9. A method of processing a memory array, comprising:
forming, on a substrate material, a first conductive line material;
forming, on the first conductive line material, a first electrode material and a second electrode material separated from one another by a sacrificial material;
forming a plurality of openings in the first conductive line, the first electrode material, the sacrificial material, and the second electrode material in a grid pattern along a first direction;
forming an insulation material in the plurality of openings;
forming, on the second electrode material and the insulation material, a second conductive line material;
forming an additional plurality of openings in the first electrode material, the sacrificial material, the second electrode material, and the second conductive line material;
forming a plurality of recesses between the first electrode material and the second electrode material along a second direction that is perpendicular to the first direction by selectively removing the sacrificial material; and
forming a chalcogenide material in the plurality of recesses.

10. The method of claim 9, wherein the method includes forming the additional plurality of openings in the first electrode material, the sacrificial material, the second electrode material, and the second conductive line material in the grid pattern to form a plurality of stacks each comprising the first electrode material, the sacrificial material, the second electrode material, and the second conductive line material.

11. The method of claim 10, further comprising removing excess chalcogenide material from along a sidewall of each respective one of the additional plurality of openings.

12. The method of claim 11, further comprising forming an additional insulation material in the additional plurality of openings such that the additional insulation material is in direct contact with the sidewall of each respective one of the plurality of openings.

13. The method of claim 9, wherein forming the chalcogenide material in the plurality of recesses further comprises depositing the chalcogenide material on the second conductive line material.

14. The method of claim 9, wherein the sacrificial material and the insulation material are different materials.

15. The method of claim 9, wherein the sacrificial material and the insulation material are a same material.

16. The method of claim 9, wherein the chalcogenide material is an alloy having a Germanium content of less than 13%.

17. A memory array, comprising:
a substrate material formed along a plane;
a plurality of stacks formed on the substrate material, wherein each respective one of the plurality of stacks includes:
a first conductive line;
a first electrode formed on the first conductive line; and
a chalcogenide material formed on the first electrode; and
a second electrode formed on the chalcogenide material; and
a second conductive line formed on the second electrode of each respective one of the plurality of stacks;
wherein the plurality of stacks are separated from one another by an insulation material in direct contact with a sidewall of each respective one of the plurality of stacks.

18. The memory array of claim 17, wherein the chalcogenide material is an alloy having a Germanium content of less than 13%.

19. The memory array of claim 17, wherein the chalcogenide material is an alloy having a glass transition temperature of less than 320 degrees Celsius.

20. The memory array of claim 17, wherein the first conductive line of each respective one of the plurality of stacks is substantially perpendicular to the second conductive line.

21. The memory array of claim 17, wherein the memory array includes a plurality of memory cells, wherein each respective one of the memory cells includes:
a first electrode of one of the plurality of stacks;
the chalcogenide material of the one of the plurality of stacks; and
the second electrode of the one of the plurality of stacks.

22. The memory array of claim 17, wherein:
the first conductive line of each respective one of the plurality of stacks is a different access line of the memory array; and
the second conductive line is a sense line of the memory array.
